(19) United States
(12) Patent Application Publication
(10) Pub. No.: US 2013/0140413 A1
(43) Pub. Date: Jun. 6, 2013

(54) Apparatus for Supporting a Portable Electronic Device

(71) Applicant: Mary Lou Bailey, Las Vegas, NV (US)

(72) Inventor: Mary Lou Bailey, Las Vegas, NV (US)

(21) Appl. No.: 13/309,430

(22) Filed: Dec. 1, 2011

(51) Int. Cl. H05K 7/00

(52) U.S. Cl. 248/201; 248/291.1

(57) ABSTRACT

An apparatus comprises a hosting frame comprising a generally U-shaped structure being operable for retaining a portable electronic device. The U-shaped structure comprises a pair of generally L-shaped hosting brackets and a collar joining the hosting brackets to form the U-shape. An extendable structure is joined to the collar. The extendable structure is operable for providing a variable length. A support bracket is rotatably joined to the extendable structure. The support bracket is operable for removably joining the apparatus to a supporting structure in which the apparatus is operable for supporting the portable electronic device at an adjustable height and an adjustable angle with respect to the supporting structure.

### FEDERALLY SPONSORED RESEARCH OR DEVELOPMENT

Not applicable.

### REFERENCE TO SEQUENCE LISTING, A TABLE, OR A COMPUTER LISTING APPENDIX

Not applicable.

### COPYRIGHT NOTICE

A portion of the disclosure of this patent document contains material that is subject to copyright protection. The copyright owner has no objection to the facsimile reproduction by anyone of the patent document or patent disclosure as it appears in the Patent and Trademark Office, patent file or records, but otherwise reserves all copyright rights whatsoever.

### FIELD OF THE INVENTION

One or more embodiments of the invention generally relate to assemblies for device retention. More particularly, the invention relates to assemblies for securing personal portable electronic devices.

### BACKGROUND OF THE INVENTION

The following background information may present examples of specific aspects of the prior art (e.g., without limitation, approaches, facts, or common wisdom) that, while expected to be helpful to further educate the reader as to additional aspects of the prior art, is not to be construed as limiting the present invention, or any embodiments thereof, to anything stated or implied therein or inferred thereupon.

Small portable personal communication and media devices are typically fabricated with a form factor capable of supporting a device for hands-free viewing while lying on a flat surface with the viewing angle for the device located in the vertical direction.

In view of the foregoing, it is clear that these traditional techniques are not perfect and leave room for more optimal approaches.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1A illustrates an example device holder, in accordance with an embodiment of the present invention;

FIG. 1B illustrates adjustment of the example device holder as described with reference to FIG. 1A, in accordance with an embodiment of the present invention;

FIG. 2 illustrates a close up view the bracket for the example device holder as described with reference to FIG. 1A, in accordance with an embodiment of the present invention;

FIGS. 3A-C illustrate a close up view the hosting frame for the example device holder as described with reference to FIG. 1A, in accordance with an embodiment of the present invention;

FIG. 4 illustrates a close up view the hosting frame for the example device holder as described with reference to FIG. 1A with an inserted device, in accordance with an embodiment of the present invention;

FIG. 5 illustrates the range of motion of example device holder as described with reference to FIG. 1A with an inserted device, in accordance with an embodiment of the present invention; and

FIG. 6 illustrates an application of example device holder as described with reference to FIG. 1A with an inserted device, in accordance with an embodiment of the present invention.

Unless otherwise indicated illustrations in the figures are not necessarily drawn to scale.

### DETAILED DESCRIPTION OF THE PREFERRED EMBODIMENTS

The present invention is best understood by reference to the detailed figures and description set forth herein.

Embodiments of the invention are discussed below with reference to the Figures. However, those skilled in the art will readily appreciate that the detailed description given herein with respect to these figures is for explanatory purposes as the invention extends beyond these limited embodiments. For example, it should be appreciated that those skilled in the art will, in light of the teachings of the present invention, recognize a multiplicity of alternate and suitable approaches, depending upon the needs of the particular application, to implement the functionality of any given detail described herein, beyond the particular implementation choices in the following embodiments described and shown. That is, there are numerous modifications and variations of the invention that are too numerous to be listed but that all fit within the scope of the invention. Also, singular words should be read as plural and vice versa and masculine as feminine and vice versa, where appropriate, and alternative embodiments do not necessarily imply that the two are mutually exclusive.

It is to be further understood that the present invention is not limited to the particular methodology, compounds, materials, manufacturing techniques, uses, and applications, described herein, as these may vary. It is also to be understood that the terminology used herein is used for the purpose of describing particular embodiments only, and is not intended to limit the scope of the present invention. It must be noted that as used herein and in the appended claims, the singular forms “a,” “an,” and “the” include the plural reference unless the context clearly dictates otherwise. Thus, for example, a reference to “an element” is a reference to one or more elements and includes equivalents thereof known to those skilled in the art. Similarly, for another example, a reference to “a step” or “a means” is a reference to one or more steps or means and may include sub-steps and subservient means. All conjunctions used are to be understood in the most inclusive sense possible. Thus, the word “or” should be understood as having the definition of a logical “or” rather than that of a logical “exclusive or” unless the context clearly necessitates otherwise. Structures described herein are to be understood also to refer to functional equivalents of such structures. Language that may be construed to express approximation should be so understood unless the context clearly dictates otherwise.

Unless defined otherwise, all technical and scientific terms used herein have the same meanings as commonly understood by one of ordinary skill in the art to which this invention belongs. Preferred methods, techniques, devices, and materials are described, although any methods, techniques, devices, or materials similar or equivalent to those described herein may be used in the practice or testing of the present invention. Structures described herein are to be understood also to refer to functional equivalents of such structures. The present invention will now be described in detail with reference to embodiments thereof as illustrated in the accompanying drawings.

From reading the present disclosure, other variations and modifications will be apparent to persons skilled in the art. Such variations and modifications may involve equivalent and other features which are already known in the art, and which may be used instead of or in addition to features already described herein.

Although Claims have been formulated in this Application to particular combinations of features, it should be understood that the scope of the disclosure of the present invention also includes any novel feature or any novel combination of features disclosed herein either explicitly or implicitly or any generalization thereof, whether or not it relates to the same invention as presently claimed in any Claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The Applicants hereby give notice that new Claims may be formulated to such features and/or combinations of such features during the prosecution of the present Application or of any further Application derived therefrom.

References to “one embodiment,” “an embodiment,” “example embodiment,” “various embodiments,” etc., may indicate that the embodiment(s) of the invention so described may include a particular feature, structure, or characteristic, but not every embodiment necessarily includes the particular feature, structure, or characteristic. Further, repeated use of the phrase “in one embodiment,” or “in an exemplary embodiment,” do not necessarily refer to the same embodiment, although they may.

As is well known to those skilled in the art many careful considerations and compromises typically must be made when designing for the optimal manufacture of a commercial implementation any system, and in particular, the embodiments of the present invention. A commercial implementation in accordance with the spirit and teachings of the present invention may configured according to the needs of the particular application, whereby any aspect(s), feature(s), function(s), result(s), component(s), approach(es), or step(s) of the teachings related to any described embodiment of the present invention may be suitably omitted, included, adapted, mixed and matched, or improved and/or optimized by those skilled in the art, using their average skills and known techniques, to achieve the desired implementation that addresses the needs of the particular application.

It is to be understood that any exact measurements/dimensions or particular construction materials indicated herein are solely provided as examples of suitable configurations and are not intended to be limiting in any way. Depending on the needs of the particular application, those skilled in the art will readily recognize, in light of the following teachings, a multiplicity of suitable alternative implementation details.

Embodiments of the present invention will be described which provide means and methods for a device holder enabling hands-free use of devices. Non-limiting examples of devices include smartphones, cellular telephones, mobile communication devices and portable video players. The device holder enables hands-free use of devices such that the devices may be maintained at or near eye-level or at other viewing angles as needed.

Device holder provides an environment such that the risk of damage to a secured device is reduced over conventionally securing a device via a person's hand or hands.

Device holder enables a user to engage in other activities while securing a device. As a non-limiting example, device holder enables a user to eat food while in use.

Personal devices may be attached to a hosting frame of device holder. Furthermore, hosting frame is attached to telescoping arm to enable extension and recession of the hosting frame.

Device holder includes a bracket for securing device holder to structures. As a non-limiting example, bracket may be used to secure device holder to the seat-back tray of an airplane. A lining may be provided within the interior area of the bracket in order to secure device holder to structures.

A hinge connects telescoping arm to the bracket. Furthermore, hinge enables movement of device holder in a direction as allowed by the hinge.

Device holder may be configured for a small form factor in order to support ease of transportation of the device holder.

Device holder may be configured in a variety of shapes, sizes, colors and materials in order to accommodate a variety of applications. Non-limiting examples of materials for fabrication include polyamide, polyester resin and acrylonitrile butadiene styrene (ABS). Device holder may also be fabricated for specific devices and/or specific applications.

In some embodiments, a containment device may be configured for storing and transporting the device holder. As a non-limiting example, containment device may be configured as a pouch.

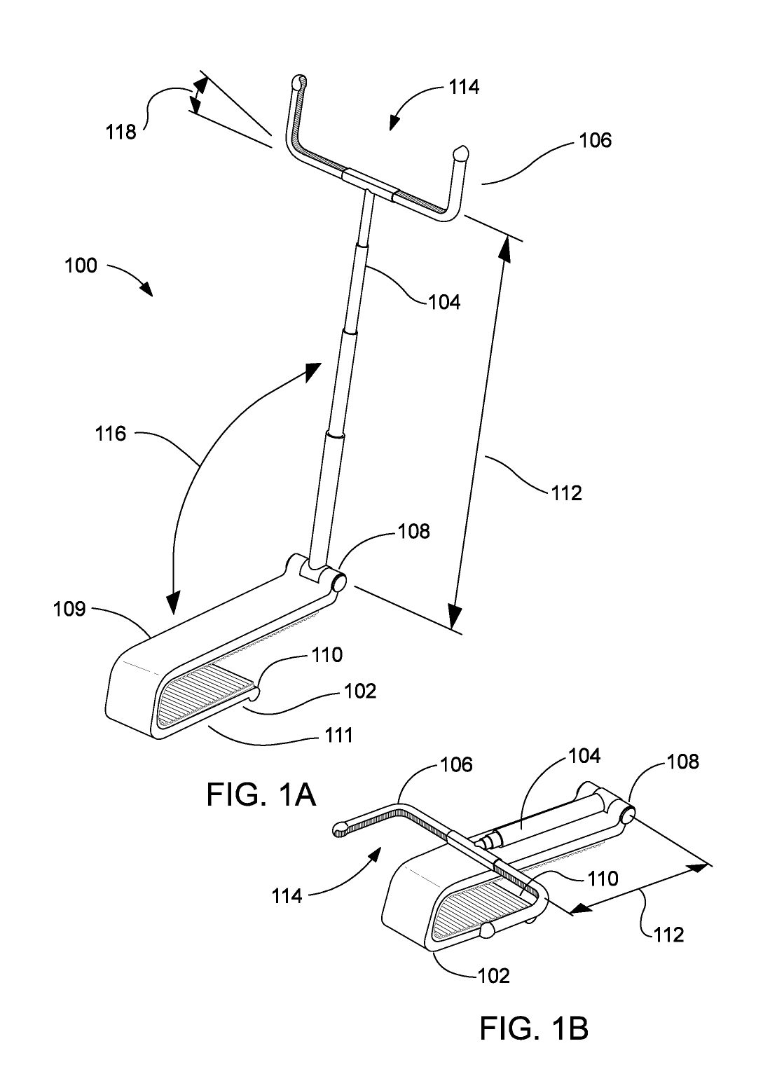

FIG. 1A illustrates an example device holder, in accordance with an embodiment of the present invention.

A device holder 100 includes a bracket 102, a telescoping arm 104 and a hosting frame 106.

Device holder 100 provides capability for securing a device to a structure. As a non-limiting example, a large portion of device holder 100 may be fabricated of polyamide with a laminated coating.

Bracket 102 provides a securing mechanism for securing device holder 100 to other structures. Non-limiting examples of structures include tables, restaurant tables, desks and seat-back trays. Bracket 102 may be configured with an additional hinge (not shown), clamp (not shown) or other securing device (not shown) in order to better secure device holder 100 to a structure.

Telescoping arm 104 provides the capability to shorten or lengthen the length between bracket 102 and hosting frame 106. Telescoping arm 104 may be configured with a multiplicity of segments. Furthermore, segments may be configured of a variety of lengths.

Hosting frame 106 provides capability for securing a device. Non-limiting examples of devices include smartphone, cellular telephone, portable electronic devices, mini laptop computer, digital camera, video camera and portable video player. Hosting frame 106 may be configured of a variety of sizes and shapes for supporting a variety of devices and/or associated applications. Hosting frame 106 may also be configured for specific devices and/or applications. Hosting frame 106 may be removed for replacement with a different hosting frame supporting alternative devices and/or applications. Hosting frame 106 may be attached to device holder 100 by any known means. Hosting frame 106 may include an extension arm (not shown) for providing support of device holder 100. Hosting frame 106 may include a rear wall/containment portion (not shown) for supporting a device. Hosting frame 106 may be configured as a supporting tray (not shown) with a rear wall/containment portion (not shown) for supporting devices of various depths, heights and widths.

Bracket 102 connects to a first end of telescoping arm 104 via a hinge 108. Hinge 108 enables the angle located between bracket 102 and telescoping arm 104 to be configured or modified. As an example, when device holder 100 is configured for storage as illustrated in FIG. 1A, the angle between bracket 102 and telescoping arm 104 may be configured as zero degrees. Hinge 108 is configured such that the angle between bracket 102 and telescoping arm 104 may be modified by a person, yet device holder 100 maintains the angle between bracket 102 and telescoping arm 104 during movement of the device. Non-limiting examples of movement associated with the device include turbulence and vibration.

Bracket 102 may be manufactured in a j-shaped configuration. Bracket 102 enables securing device holder 100 to a structure. A space 110 allows insertion of a structure into space 110 for securing device holder 100 to the structure. As a non-limiting example, a top plane 109 of bracket 102 measures six inches in length and a bottom plane 111 of bracket 102 measures two and one half inches in length. As a non-limiting example, space 110 may be configured for one inch of separation between top plane 109 and bottom plane 111. Bottom plane 111 may be slightly angled in a downward direction in order to allow a wider opening at the edge of the device for ease of slipping bracket 102 over a structure. In some embodiments, bracket 102 may be configured as more of a shelf in order to support larger devices.

Telescoping arm 104 may be extended or recessed to provide differing length dimensions for a length 112. Telescoping arm 104 may be configured of a multiplicity of segments. As a non-limiting example, telescoping arm 104 may be configured of four segments. As a non-limiting example, the base and longest segment of telescoping arm 104 may measure approximately four inches in length. As a non-limiting example, length 112 of telescoping arm 104 may be extended to fifteen inches in length.

Hosting frame 106 attaches to a second end of telescoping arm 104.

Hosting frame 106 may be manufactured in a u-shaped configuration.

Hosting frame 106 includes an interior space 114 for receiving and securing devices. Hosting frame 106 may be rotated with respect to telescoping arm 104. The size of interior space 114 may be modified to support a variety of devices. In some embodiments, hosting frame may be configured with a larger size than typical in order to support securing larger devices.

In operation, a user secures device holder 100 to a structure (not shown) via bracket 102. Force is applied to telescoping arm 104 and/or hosting frame 106 in order to increase the angle between telescoping arm 104 and bracket 102. Telescoping arm is extended via application of force. Interior space 114 is increased via application of force such that a portable communication device may be inserted into hosting frame 106. Hosting frame 106 is rotated via application of force. As a non-limiting example, a person sitting on an airplane may seek to watch a movie on their portable communication device. The person connects the holding device to the fold-down seat-back located in front of the person. The person then adjusts the holding device for proper viewing of a portable communication device. During use, the person experiences hands-free use of the portable communication device. Furthermore, the person may configure device holder 100 such that the person experiences proper neck and spinal positioning. Following use, person may remove the portable communication device, recess telescoping arm 104 and fold telescoping arm 104 flat against bracket 102 such that the device holder is arranged for its most compact configuration for convenient storage as illustrated in FIG. 1A.

FIG. 1A illustrates an example device holder such that a device available for viewing may be inserted into the device holder for securing to a structure and to provide adjustment for viewing device, in accordance with an embodiment of the present invention.

FIG. 1B illustrates adjustment of the example device holder as described with reference to FIG. 1A, in accordance with an embodiment of the present invention.

An angle 116 with respect to bracket 102 and telescoping arm 104 has been increased to ninety degrees as compared to FIG. 1A.

Length 112 associated with telescoping arm 104 has been increased as compared to FIG. 1A.

An angle 118 has be been modified as compared to FIG. 1A in order to provide viewing located to the left of bracket 102.

FIG. 1B illustrates adjustment of the example device holder as described with reference to FIG. 1A in order to provide a variety of viewing angles.

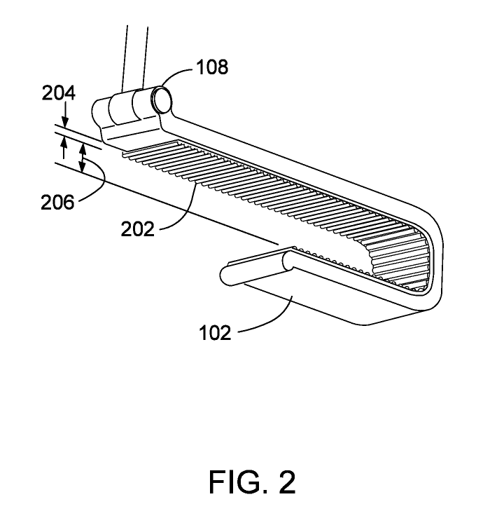

FIG. 2 illustrates a close up view the bracket for the example device holder as described with reference to FIG. 1A, in accordance with an embodiment of the present invention.

A lining 202 is configured within the interior of bracket 102. As a non-limiting example, lining 202 may be configured of rubber, nylon or encased gelatin. In some configurations, bracket 102 may be fabricated without lining 202.

Lining 202 has a depth dimension noted as a depth 204. As a non-limiting example, depth 204 may be one-eighth of one inch in depth.

The distance between the interior surfaces of rubber lining is noted as a separation 206. As a non-limiting example, separation 206 may be configured as three-quarters of one inch.

FIG. 2 illustrates a close up view of the lining for the bracket of the example device holder as described with reference to FIG. 1A.

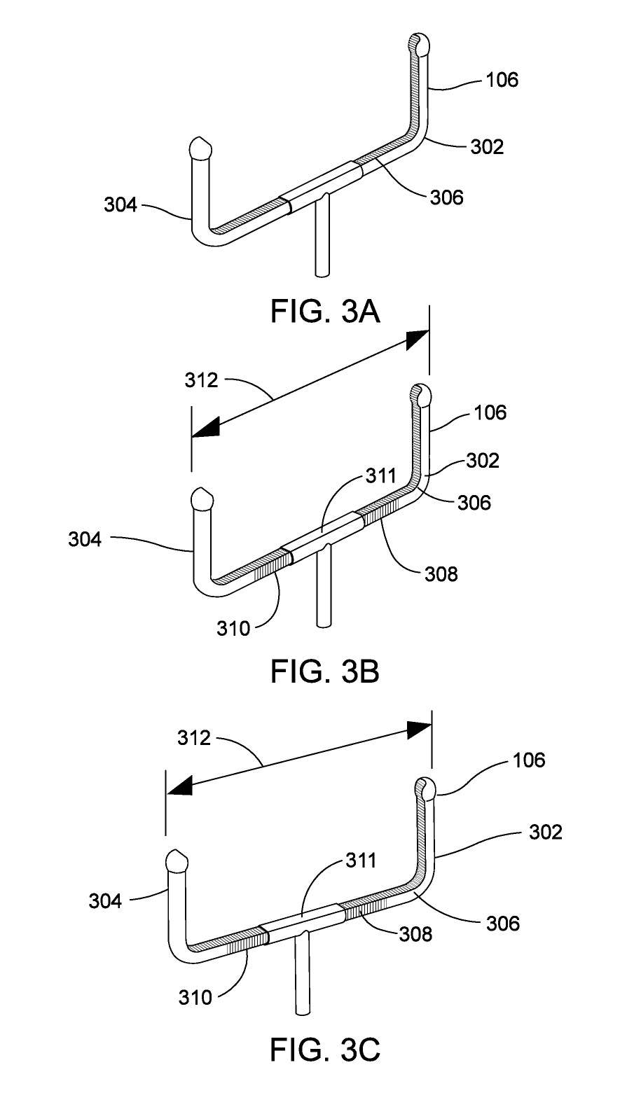

FIG. 3A illustrates a close up view the hosting frame for the example device holder as described with reference to FIG. 1A, in accordance with an embodiment of the present invention.

Hosting frame 106 include a bracket 302 and a bracket 304. As a non-limiting example, bracket 302 and bracket 304 may be configured in an L-shape.

The interior planes of bracket 302 and bracket 304 include a channel 306 for securing a device. As a non-limiting example, channel 306 is textured for providing additional friction for securing device.

FIG. 3A illustrates a close up view the hosting frame for the example device holder as described with reference to FIG. 1A, where hosting frame is configured of brackets with channels for securing a device.

FIG. 3B illustrates a close up view the hosting frame for the example device holder as described with reference to FIG. 1A, in accordance with an embodiment of the present invention.

Bracket 302 includes a spring 308 and bracket 304 includes a spring 310.

Spring 308 and spring 310 provide tension to bracket 302 and bracket 304, respectively, for enabling extension of bracket 302 and bracket 304 and for allowing insertion and retention of a device. A first endpoint of spring 308 is attached to the right portion for bracket 302 and spring 310 is attached to the left portion for bracket 304.

A cylindrical collar 311 encloses the end points where a second endpoint of spring 308 and a second endpoint of spring 310 are attached. Cylindrical collar 311 enables the formation of a U-shaped bracket allowing the extension and recession of bracket 302 and bracket 304 for maintaining a uniform attachment to a device.

Extension of bracket 302 and bracket 304 provides for modification of the distance between bracket 302 and bracket 304 noted as a separation 312. Separation 312 enables insertion of a device.

FIG. 3B illustrates a close up view the hosting frame for the example device holder as described with reference to FIG. 1A where a spring enables extension of hosting frame 106 for insertion and retention of a device.

FIG. 3C illustrates a close up view the hosting frame for the example device holder as described with reference to FIG. 1A, in accordance with an embodiment of the present invention.

Force has been applied to bracket 302 and bracket 304 for increasing the distance associated with separation 312 as compare to FIG. 3B. Furthermore, the tension force associated with spring 308 and spring 310 has been increased.

FIG. 3C illustrates a close up view the hosting frame for the example device holder as described with reference to FIG. 1A where a force applied to the brackets associated with the frame holder separates the brackets.

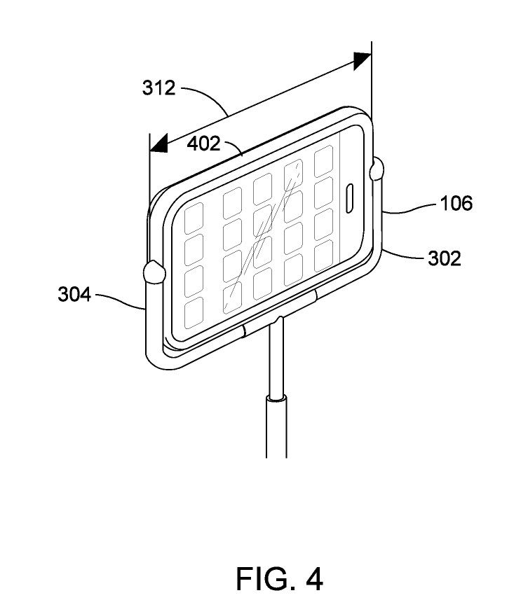

FIG. 4 illustrates a close up view the hosting frame for the example device holder as described with reference to FIG. 1A with an inserted device, in accordance with an embodiment of the present invention.

A device 402 is inserted into hosting frame 106. Non-limiting examples for device 402 include smartphone, cellular telephone and video player.

Device 402 may be inserted into hosting frame 106 by applying an outward force to bracket 302 and/or bracket 304 which increases separation 312 such that device 402 may be inserted into hosting frame 106. Furthermore, once device 402 is inserted into hosting frame 106, outward force may be removed in order for bracket 302 and bracket 304 to secure device 402.

FIG. 4 illustrates a close up view the hosting frame for the example device holder as described with reference to FIG. 1A with an inserted device where an outward force applied to brackets enables insertion of a device followed by removal of force to allow securing the device.

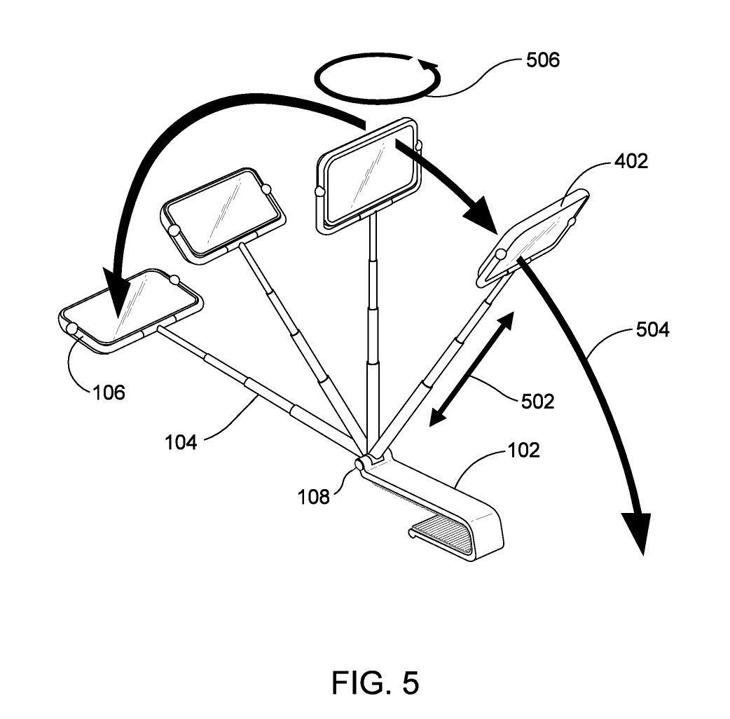

FIG. 5 illustrates the range of motion of example device holder as described with reference to FIG. 1A with an inserted device, in accordance with an embodiment of the present invention.

A telescoping arm motion 502 describes the motion of hosting frame 106 as telescoping arm 104 is extended and recessed via application of forces for extension and recession.

A hinge motion 504 describes the motion of hosting frame 106 as force is applied to hosting frame 106 and/or telescoping arm 104 for moving hosting frame 106 in the general direction of the applied force as allowed by hinge 108.

A rotation motion 506 describes the motion of hosting frame 106 as force is applied to hosting frame 106 in order for hosting frame 106 to rotate.

FIG. 5 illustrates the range of motion of example device holder as described with reference to FIG. 1A with an inserted device where the device may experience a telescoping motion, a hinging motion and a rotation motion.

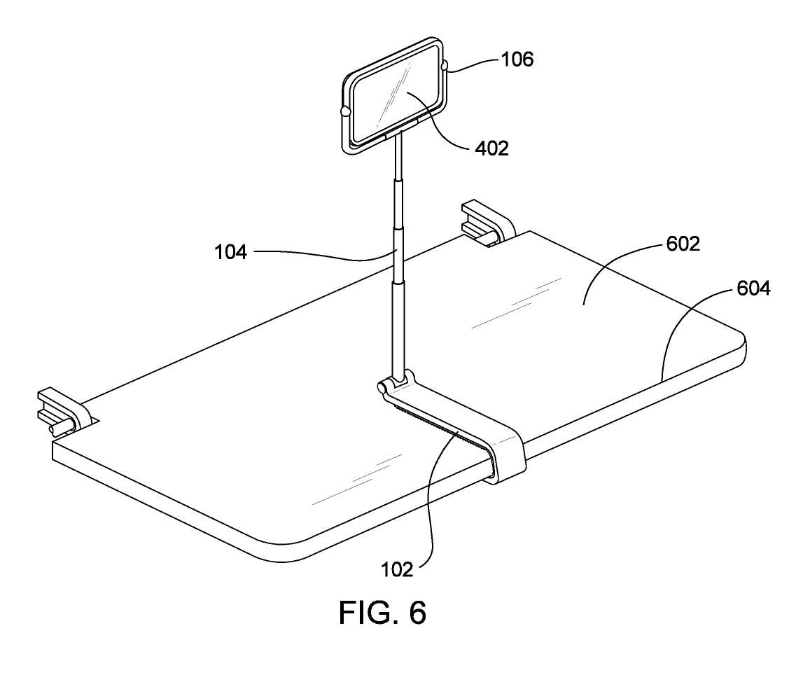

FIG. 6 illustrates an application of example device holder as described with reference to FIG. 1A with an inserted device, in accordance with an embodiment of the present invention.

Bracket 102 traverses a seat-back tray 602. Furthermore, bracket 102 traverses an edge 604 of seat-back tray 602. As a non-limiting example, a user seeks to watch a video via device 402. Furthermore, user slides bracket 102 over edge 604 such that bracket 102 traverses a portion of seat-back tray 602. Furthermore, user adjusts height of telescoping arm 104, angle between telescoping arm 104 and bracket 102 and rotation of hosting frame 106.

FIG. 6 illustrates an application of example device holder as described with reference to FIG. 1A with an inserted device where device holder is secured to a structure such that device holder may be adjusted for viewing a device.

All the features disclosed in this specification, including any accompanying abstract and drawings, may be replaced by alternative features serving the same, equivalent or similar purpose, unless expressly stated otherwise. Thus, unless expressly stated otherwise, each feature disclosed is one example only of a generic series of equivalent or similar features.

Having fully described at least one embodiment of the present invention, other equivalent or alternative assemblies for securing personal portable electronic devices according to the present invention will be apparent to those skilled in the art. The invention has been described above by way of illustration, and the specific embodiments disclosed are not intended to limit the invention to the particular forms disclosed. For example, the particular implementation of the hosting frame may vary depending upon the particular type of device secured. The devices described in the foregoing were directed to portable communications devices implementations; however, similar techniques applied to game device implementations of the present invention are contemplated as within the scope of the present invention. The invention is thus to cover all modifications, equivalents, and alternatives falling within the spirit and scope of the following claims.

Claim elements and steps herein may have been numbered and/or lettered solely as an aid in readability and understanding. Any such numbering and lettering in itself is not intended to and should not be taken to indicate the ordering of elements and/or steps in the claims.

What is claimed is:

1. An apparatus comprising:
a hosting frame comprising a generally U-shaped structure being operable for retaining a portable electronic device, said U-shaped structure comprising a pair of generally L-shaped hosting brackets and a collar joining said hosting brackets to form said U-shape;
an extendable structure being joined to said collar, said extendable structure being operable for providing a variable length; and
a support bracket being rotatably joined to said extendable structure, said support bracket being operable for removably joining the apparatus to a supporting structure in which the apparatus is operable for supporting the portable electronic device at an adjustable height and an adjustable angle with respect to the supporting structure.

2. The apparatus as recited in claim 1, in which said hosting frame is rotatable about at least two axes.

3. The apparatus as recited in claim 1, further comprising a hinge structure joining said support bracket to said extendable structure in which an angle between said support bracket and said extendable structure is adjustable.

4. The apparatus as recited in claim 3, in which said hinge structure is further operable for enabling rotation about an axis generally parallel to a plane of the support structure.

5. The apparatus as recited in claim 3, in which said hinge structure is further operable for enabling said extendable structure to rotate to a position generally parallel to said support bracket during transportation and storage of the apparatus.

6. The apparatus as recited in claim 1, in which each of said hosting brackets further comprises a spring structure being configured for enabling extension of said U-shaped structure.

7. The apparatus as recited in claim 6, in which said spring structures are joined to said collar.

8. The apparatus as recited in claim 1, in which each of said hosting brackets further comprises a channel being configured for securing the portable electronic device.

9. The apparatus as recited in claim 8, in which said channels comprise a textured surface being configured for further securing the portable electronic device.

10. The apparatus as recited in claim 1, in which said extendable structure further comprises telescoping sections.

11. The apparatus as recited in claim 10, in which said telescoping sections are tubular.

12. The apparatus as recited in claim 1, in which said extendable structure is further operable for enabling said hosting frame to rotate about a longitudinal axis of said extendable structure.

13. The apparatus as recited in claim 1, in which said support bracket further comprises a J-shaped member being configured to be operable for joining to a generally flat surfaced supporting structure.

14. The apparatus as recited in claim 13, in which an interior of said J-shaped member comprises a lining being configured for contacting the flat surfaced supporting structure.

15. The apparatus as recited in claim 13, in which said J-shaped member is further configured to be operable for joining to a seat-back tray.

16. An apparatus comprising:
means being operable for expansively retaining a portable electronic device;
means, being joined to said retaining mean, being operable for adjusting an extension length from said retaining means and being operable for enabling said retaining mean to rotate about a longitudinal axis of said adjusting means; and
means being operable for removably joining the apparatus to a supporting structure; and
means, joining said joining means to said adjusting means, being operable for enabling rotation about an axis generally parallel to a plane of the support structure for adjusting an angle between said joining means and said adjusting means in which the apparatus is operable for supporting the portable electronic device at an adjustable height and adjustable angles with respect to the supporting structure.

17. An apparatus comprising:
a hosting frame comprising a generally U-shaped structure being operable for retaining a portable electronic device, said U-shaped structure comprising a pair of generally L-shaped hosting brackets, each of said hosting brackets further comprising a spring structure being configured for enabling extension of said U-shaped structure, each of said hosting brackets further comprising a channel comprising a textured surface being configured for securing the portable electronic device, said U-shaped structure further comprising a collar joining said spring structures of said hosting brackets to form said U-shape;
an extendable structure being joined to said collar, said extendable structure comprising tubular telescoping sections being operable for providing a variable length and for enabling said hosting frame to rotate about a longitudinal axis of said extendable structure; and
a support bracket being operable for removably joining the apparatus to a supporting structure, said support bracket further comprising a J-shaped member being configured to be operable for joining to a generally flat surfaced supporting structure; and
a hinge structure being operable for joining said support bracket to said extendable structure, said hinge structure being further operable for enabling rotation about an axis generally parallel to a plane of the support structure for adjusting an angle between said support bracket and said extendable structure in which the apparatus is operable for supporting the portable electronic device at an adjustable height and adjustable angles with respect to the supporting structure.

18. The apparatus as recited in claim 17, in which said hinge structure is further operable for enabling said extendable structure to rotate to a position generally parallel to said support bracket during transportation and storage of the apparatus.

19. The apparatus as recited in claim 17, in which an interior of said J-shaped member further comprising a lining being configured for contacting the flat surfaced supporting structure.

20. The apparatus as recited in claim 17, in which said J-shaped member is further configured to be operable for joining to a seat-back tray.
